(19) United States
(12) Patent Application Publication
(10) Pub. No.: US 2026/0060111 A1
(43) Pub. Date: Feb. 26, 2026

(54) PACKAGE SUBSTRATE, SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventor: Daae KO, Suwon-si (KR)

(21) Appl. No.: 19/196,299

(22) Filed: May 1, 2025

(30) Foreign Application Priority Data
Aug. 22, 2024 (KR) 10-2024-0112508

(51) Int. Cl. H01L 23/00; H01L 23/498

(52) U.S. Cl. CPC H01L 24/85; H01L 23/49838; H01L 24/48; H01L 2224/48227; H01L 2224/85385; H01L 2224/85444; H01L 2224/85447; H01L 2224/85455

(57) ABSTRACT

A package substrate includes at least one insulating layer, upper circuit wirings having a plurality of pad patterns that extend on the at least one insulating layer, and a plurality of plating patterns respectively on the plurality of pad patterns. Each of the pad patterns has a geometric characteristic of surface waviness. Each of the plating patterns covers a surface of each of the pad patterns and has a geometric characteristic of predetermined surface roughness.

### PRIORITY STATEMENT

This application claims priority under 35 U.S. C. § 119 to Korean Patent Application No. 10-2024-0112508, filed on Aug. 22, 2024 in the Korean Intellectual Property Office (KIPO), the contents of which are herein incorporated by reference in their entirety.

### FIELD

Example embodiments relate to a package substrate, a semiconductor package and a method of manufacturing the semiconductor package. More particularly, example embodiments relate to a package substrate, a semiconductor package including the package substrate, and a method for manufacturing the same.

### BACKGROUND

In manufacturing a semiconductor package, a semiconductor chip may be placed on a package substrate, and bonding wires may be used to connect chip pads of the semiconductor chip and bond fingers of the package substrate. A pitch between the bond fingers may be gradually becoming finer, and there is a problem in that a defect may occur in a wire bonding process because a sufficient bonding area with the wire is not secured on a surface of the bond finger.

### SUMMARY

Example embodiments provide a package substrate having bond fingers capable of improving a process efficiency and yield of a wire bonding process.

Example embodiments provide a semiconductor package including the above package substrate.

Example embodiments provide a method of manufacturing the above semiconductor package.

According to example embodiments, a package substrate includes at least one insulating layer, upper circuit wirings having a plurality of pad patterns that extend on the at least one insulating layer, and a plurality of plating patterns respectively on the plurality of pad patterns. Each of the plurality of pad patterns has a geometric characteristic of surface waviness. Each of the plurality of plating patterns covers a surface of each of the pad patterns and has a geometric characteristic of predetermined surface roughness.

According to example embodiments, a package substrate includes a plurality of insulating layers, upper circuit wirings having a plurality of pad patterns that extend on an uppermost insulating layer among the plurality of insulating layers, an upper protective layer covering the uppermost insulating layer and having a recess that expose the plurality of pad patterns, and a plurality of plating patterns respectively on the plurality of pad patterns that are exposed within the recess. Each of the plurality of pad patterns exposed within the recess has a geometric characteristic of surface waviness. Each of the plurality of plating patterns has a geometric characteristic of predetermined surface roughness.

According to example embodiments, a semiconductor package includes a package substrate including a plurality of bond fingers, at least one semiconductor chip on the package substrate and including a plurality of chip pads, and bonding wires electrically connecting the plurality of chip pads and the plurality of bond fingers. Each of the plurality of bond fingers includes a pad pattern on an upper surface of the package substrate and having a geometric characteristic of surface waviness, and a plating pattern covering a surface of the pad pattern and having a geometric characteristic of predetermined surface roughness. One end portion of the bonding wire is bonded to an upper surface of the plating pattern of a corresponding bond finger. A vertical distance between a lowest point and a highest point of a surface profile of the pad pattern is within a range of 2 μm to 10 μm. An average roughness of a surface profile of the plating pattern is within a range of 0.1 μm to 1 μm.

According to example embodiments, in a method of manufacturing a semiconductor package, a plurality of insulating layers are provided. Upper circuit wirings including a plurality of pad patterns are formed on an uppermost insulating layer among the plurality of insulating layers, each of the plurality of pad patterns having a geometric characteristic of surface waviness. An upper protective layer is formed to cover the uppermost insulating layer, the upper protective layer including a recess that exposes the plurality of pad patterns. Preliminary plating patterns are formed respectively on the plurality of pad patterns that are exposed within the recess. Surfaces of the preliminary plating patterns are flattened to form plating patterns having a geometric characteristic of predetermined surface roughness. At least one semiconductor chip including a plurality of chip pads is positioned on the upper protective layer. The plurality of chip pads and the plating patterns are electrically connected to each other using a plurality of bonding wires.

In example embodiments, forming the upper circuit wirings including the plurality of pad patterns on the uppermost insulating layer may include forming a seed layer on the uppermost insulating layer; forming a first photoresist pattern having first openings that expose finger body regions on the seed layer; and performing a plating process to fill the first openings with a metal material to form the plurality of pad patterns.

In example embodiments, a vertical distance between a lowest point and a highest point of a surface profile of each of the pad patterns may be within a range of 2 μm to 10 μm.

In example embodiments, forming the preliminary plating patterns on the plurality of pad patterns respectively may include performing a first plating process to form first preliminary plating patterns on the pad patterns respectively; and performing a second plating process to form second preliminary plating patterns on the first preliminary plating patterns respectively.

In example embodiments, each of the first preliminary plating patterns may include nickel (Ni), and each of the second preliminary plating patterns includes gold (Au).

In example embodiments, each of the first preliminary plating patterns may have a thickness within a range of 4 μm to 8 μm, and each of the second preliminary plating patterns may have a thickness within a range of 0.1 μm to 1.5 μm.

In example embodiments, flattening the surfaces of the preliminary plating patterns may include providing a flattening apparatus having a protrusion portion that has a pressurizing surface; and contacting and pressing the surfaces of the preliminary plating patterns with the pressurizing surface of the protrusion portion of the flattening apparatus.

In example embodiments, flattening the surfaces of the preliminary plating patterns may further include controlling temperature of the protrusion portion that contacts and presses the surfaces of the preliminary plating patterns, by a heater.

In example embodiments, the pressurizing surface of the protrusion portion may have a geometric characteristic of the predetermined surface roughness, and a surface roughness of the pressurizing surface may be transferred to the surface of the preliminary plating pattern, so that the plating pattern has the geometric characteristics of the predetermined surface roughness.

In example embodiments, an average roughness of a surface profile of each of the plating patterns may be within a range of 0.1 μm to 1 μm.

According to example embodiments, a semiconductor package may include a package substrate including a plurality of bond fingers, a semiconductor chip on the package substrate and including a plurality of chip pads, and bonding wires that electrically connect the plurality of chip pads and the plurality of bond fingers. Each of the bond fingers may include a pad pattern having a geometric characteristic of surface waviness, and a plating pattern covering a surface of the pad pattern and having a geometric characteristic of predetermined surface roughness.

The plating pattern may be formed by forming a preliminary plating pattern on the pad pattern by a plating process and then flattening a surface of the preliminary plating pattern. Since the preliminary plating pattern is formed along a surface profile of the pad pattern, the preliminary plating pattern may have a surface waviness that is the same as or similar to the surface waviness of the pad pattern. By pressing the surface of the preliminary plating pattern using a flattening apparatus, the geometric characteristic of the surface waviness may be removed from the surface profile of the preliminary plating pattern.

Accordingly, since the plating pattern does not have the geometric characteristic of surface waviness, the bond finger may provide a flat upper surface. In addition, since the plating pattern has the geometric characteristics of predetermined surface roughness, the process efficiency and yield in a wire bonding process may be improved.

### BRIEF DESCRIPTION OF THE DRAWINGS

Example embodiments will be more clearly understood from the following detailed description taken in conjunction with the accompanying drawings. FIGS. 1 to 22 represent non-limiting, example embodiments as described herein.

FIG. 1 is a plan view illustrating a semiconductor package in accordance with example embodiments.

FIG. 2 is a cross-sectional view taken along the line A1-A1′ in FIG. 1.

FIG. 3 is a cross-sectional view taken along the line B1-B1′ in FIG. 1.

FIG. 4 is a cross-sectional view taken along the line C1-C1′ in FIG. 1.

FIG. 5 is an enlarged cross-sectional view illustrating portion ‘D’ in FIG. 3.

FIG. 6 is a perspective view illustrating a portion of the semiconductor package of FIG. 1.

FIGS. 7 to 22 are views illustrating a method of manufacturing a semiconductor package in accordance with example embodiments.

### DETAILED DESCRIPTION

Hereinafter, example embodiments will be explained in detail with reference to the accompanying drawings.

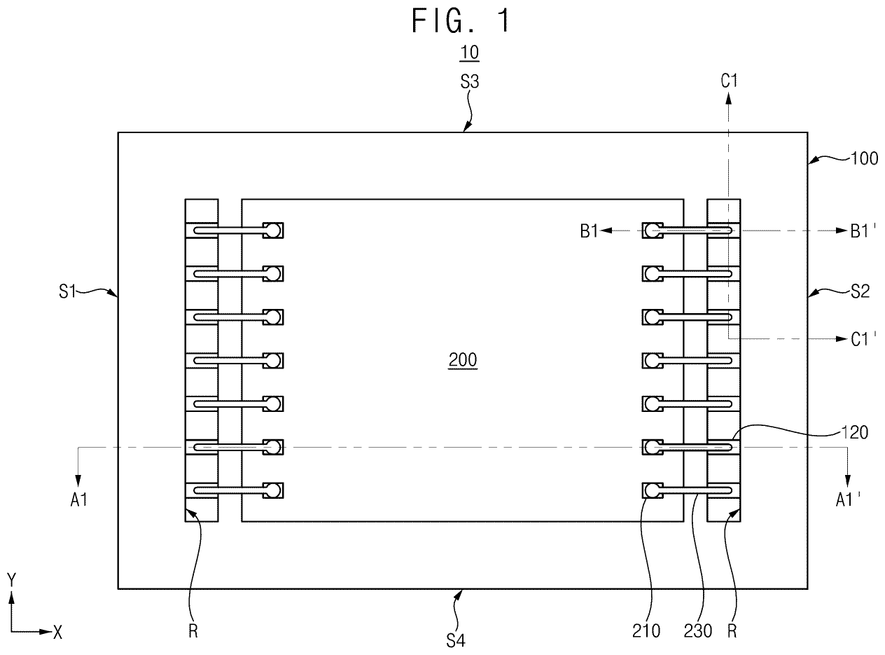

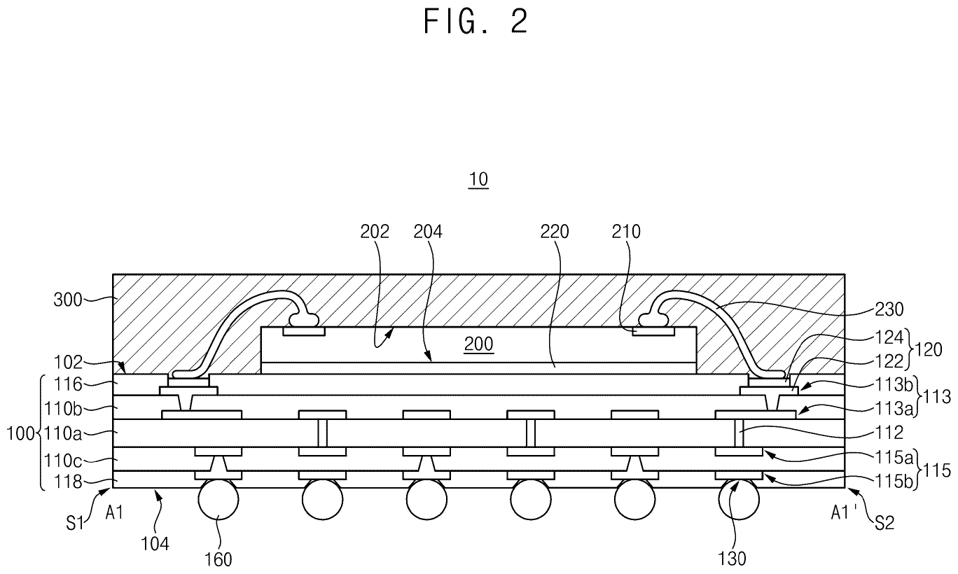

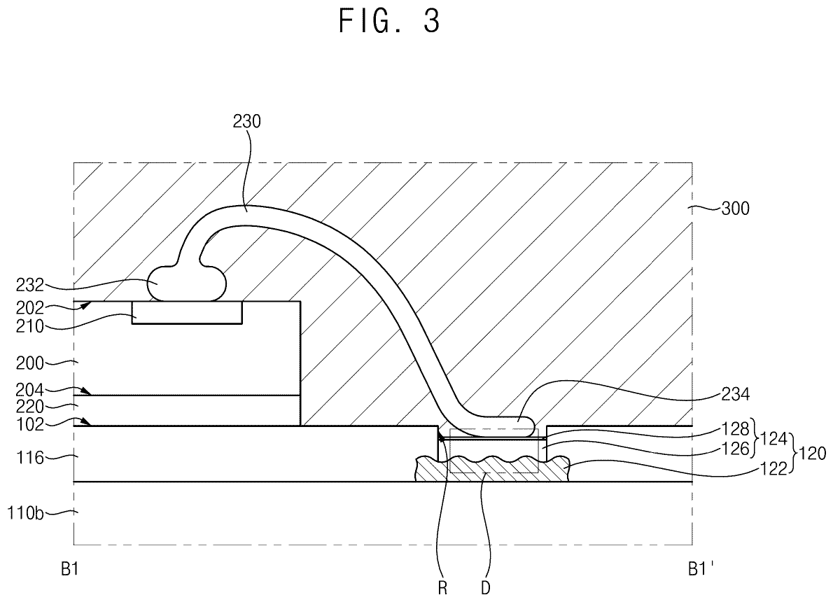

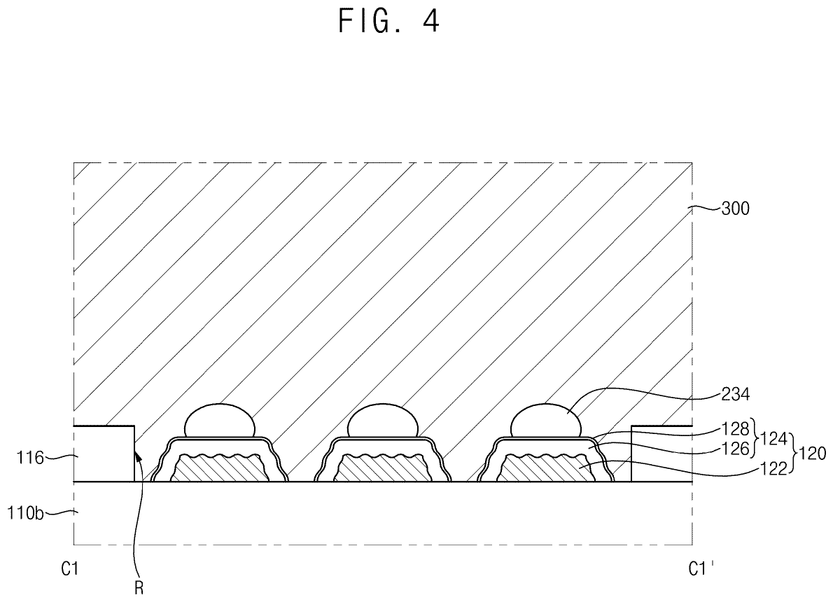

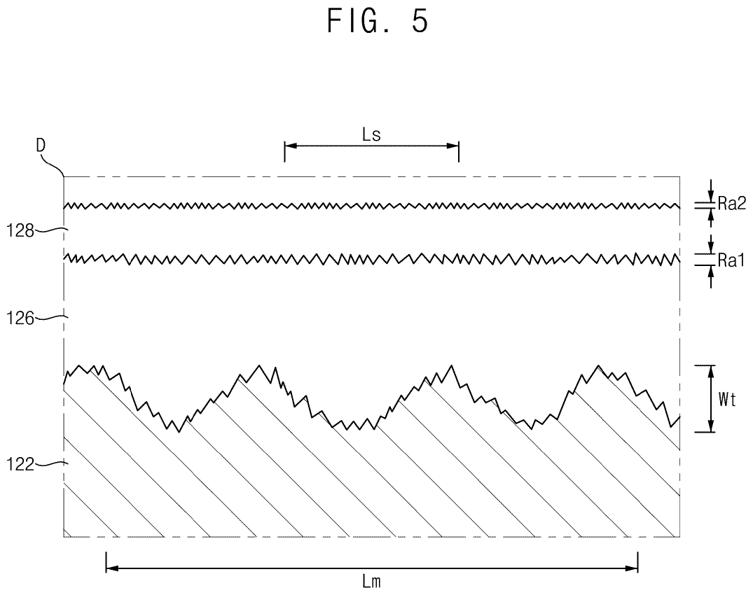

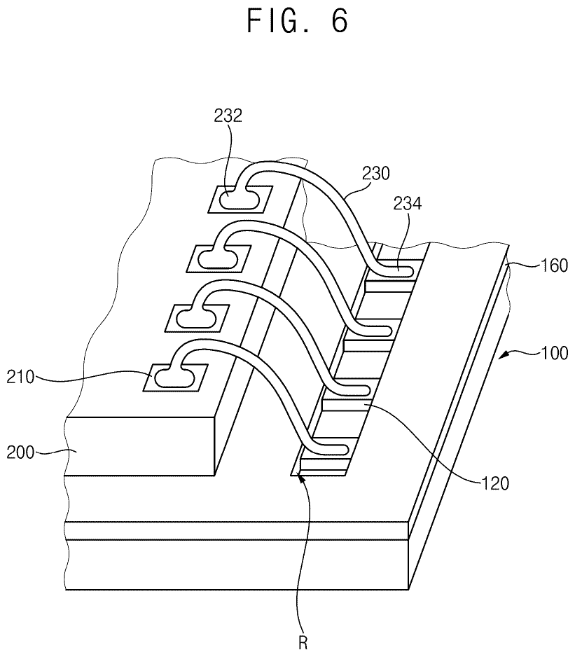

FIG. 1 is a plan view illustrating a semiconductor package in accordance with example embodiments. FIG. 2 is a cross-sectional view taken along the line A1-A1′ in FIG. 1. FIG. 3 is a cross-sectional view taken along the line B1-B1′ in FIG. 1. FIG. 4 is a cross-sectional view taken along the line C1-C1′ in FIG. 1. FIG. 5 is an enlarged cross-sectional view illustrating portion ‘D’ in FIG. 3. FIG. 6 is a perspective view illustrating a portion of the semiconductor package of FIG. 1. FIG. 1 is a plan view illustrating the semiconductor package, wherein a molding member in FIG. 2 is omitted.

Referring to FIGS. 1 to 6, a semiconductor package 10 may include a package substrate 100, at least one semiconductor chip 200, and a plurality of bonding wires 230. In addition, the semiconductor package 100 may further include a molding member 300 and external connection members 160.

In example embodiments, the package substrate 100 may be a substrate having an upper surface 102 and a lower surface 104 opposite to the upper surface 102. For example, the package substrate 100 may include a printed circuit board PCB, a flexible substrate, a tape substrate, etc. The printed circuit board may be a multilayer circuit board having vias and various circuits therein.

The package substrate 100 may include a first side portion or first side surface S1 and a second side portion or second side surface S2 extending in a direction parallel to a second direction (Y direction) and facing each other, and a third side portion or third side surface S3 and a fourth side portion or fourth side surface S4 extending in a direction parallel to a first direction (X direction) perpendicular to the second direction and facing each other.

The package substrate 100 may have a chip mounting region in a central region thereof. The chip mounting region may be a region where the semiconductor chip 200 is mounted. The chip mounting region may have a rectangular shape. The package substrate 100 may include a plurality of bond fingers 120 arranged adjacent to the chip mounting region. The bond fingers 120 may be connected to the wirings respectively. The wirings may extend from the upper surface 102 or within the package substrate 100.

Although only a few bond fingers are illustrated in the figures, it will be understood that the number, shape and arrangement of the bond fingers are provided by way of example and that the present inventive concept is not limited thereto.

As illustrated in FIG. 2, the package substrate 100 may include a plurality of insulating layers 110a, 110b, 110c and wirings 113, 115 provided in the insulating layers respectively.

In particular, the package substrate 100 may include a core layer 110a, an upper insulating layer 110b on an upper surface of the core layer 110a, and a lower insulating layer 110c on a lower surface of the core layer 110a. The package substrate 100 may include a plurality of through vias 112 penetrating the core layer 110a, first upper circuit wirings 113a on the upper surface of the core layer 110a, second upper circuit wirings 113b provided in or on the upper insulating layer 110b, first lower circuit wirings 115a on the lower surface of the core layer 110a, and second lower circuit wirings 115b provided in or on the lower insulating layer 110c.

In example embodiments, the second upper circuit wirings 113b may include a plurality of pad patterns 122 that are exposed from a recess R and are provided as portions of bond fingers (finger bodies). The second upper circuit wiring 113b may extend on the upper insulating layer 110b and may include a trace including the pad pattern and a via pattern that is electrically connect to the first upper circuit wiring 113a through an opening formed in the upper insulating layer 110b.

In example embodiments, the package substrate 100 may include an upper protective layer 116 having the recess R that exposes the plurality of pad patterns 122. The upper protective layer 116 may cover the entire upper surface of the upper insulating layer 110b except for the pad patterns 122. An upper surface of the upper protective layer 116 may be provided as the upper surface 102 of the package substrate 100.

For example, two recesses R may extend in the second direction (Y direction) along or adjacent the first side portion S1 and the second side portion S2 of the package substrate 100, respectively. The recess R may be elongated and may have, for example, a rectangular shape. The plurality of pad patterns 122 may be spaced apart from each other along the second direction (Y direction) within the recess R. Each of the pad patterns 122 may extend within the recess R in the first direction (X direction). The pad patterns 122 may be exposed from a bottom surface of the recess R. A thickness of the pad pattern 122 may be within a range of 5 μm to 30 μm. A width of the pad pattern 122 in the first direction (X direction) may be within a range of 30 μm to 40μm. The pad pattern 122 may include copper (Cu).

Additionally, the package substrate 100 may include a lower protective layer 118 that is provided on the lower surface of the lower insulating layer 110c and at least partially covers the second lower circuit wirings 115b. A lower surface of the lower protective layer 118 may be provided as the lower surface 104 of the package substrate 100. At least a portion of a pad of the second lower circuit wiring 115b may be provided as a lower substrate pad 130.

In example embodiments, each of the bond fingers 120 may include a pad pattern 122 extending within the recess R and a plating pattern 124 covering a surface of the pad pattern 122. The plating pattern 124 may include a first plating pattern 126 on the pad pattern 122 and a second plating pattern 128 on the first plating pattern 126.

For example, the first plating pattern 126 may include nickel (Ni), and the second plating pattern 128 may include gold (Au). The first plating pattern 126 may have a thickness within a range of 4 μm to 8 μm, and the second plating pattern 128 may have a thickness within a range of 0.1 μm to 1.5 μm.

In example embodiments, the semiconductor chip 200 may be mounted on the chip mounting region of the package substrate 100. The semiconductor chip 200 may be mounted on the package substrate 100 by a wire bonding method. The semiconductor chip 200 may be placed such that a surface 204 (e.g., a back surface or lower surface) opposite to a front surface 202 (e.g., upper surface) on which chip pads 210 are formed, i.e., an active surface, faces the package substrate 100. The semiconductor chip 200 may have a rectangular shape with four sides when viewed in a plan view. The chip pads 210 may be arranged on the front surface 202 of the semiconductor chip 200 to be spaced apart from each other along or adjacent first and second sides facing each other.

The semiconductor chip 200 may be attached to the package substrate 100 by an adhesive film 220. The chip pads 210 of the semiconductor chip 200 may be electrically connected to the bond fingers 120 of the package substrate 100 by bonding wires 230 as conductive connection members. One end portion 232 (e.g., including a first end) of the bonding wire 230 may be bonded to the chip pad 210, and the other end portion 234 (e.g., including an opposite second end) of the bonding wire 230 may be bonded to an upper surface of the plating pattern 124 of the corresponding bond finger 120. For example, a thickness of the semiconductor chip 200 may be within a range of 40 μm to 120 μm. A thickness of the adhesive film 220 may be within a range of 5 μm to 30 μm.

As illustrated in FIGS. 3 to 5, each of the pad patterns 122 may have a geometric characteristic of surface waviness. The surface waviness of the pad pattern 122 may be represented by a vertical distance (profile height) Wt between a lowest point and a highest point of the surface profile. For example, the profile height Wt of the pad pattern 122 may be within a range of 2 μm to 10 μm. Each of the pad patterns 122 may further have a geometric characteristic of surface roughness. The plating pattern 124 may have a geometric characteristic of predetermined surface roughness. The surface roughness of the plating pattern 124 may be represented by an average roughness (Ra, Roughness average), which is an average value of roughness within a roughness reference length (Ls). For example, the average roughness of the surface profile of the plating pattern 124 (the average roughness of the second plating pattern, Ra2) may be within a range of 0.1 μm to 1 μm.

The surface waviness may be a surface waviness that appears at a larger interval than an interval of the surface roughness. The surface waviness may be a waviness having a longer period and a larger amplitude than the surface roughness. The profile height Wt of the surface waviness may be determined within a waviness reference length (measurement section, Lm). The surface roughness may indicate the degree of surface irregularity within a relatively small range. The surface roughness may be determined within a roughness reference length (Ls). The waviness reference length (Lm) may be equal to or smaller than a width of the upper surface of the pad pattern 122 (for example, the width in the first direction (X direction)). The waviness reference length (Lm) may be within a range of 10 μm to 40 μm. The roughness reference length (Ls) may be smaller than the waviness reference length (Lm). The roughness reference length (Ls) may be in a range of 1 μm to 5 μm.

Since the plating pattern 124 does not have the geometric characteristic of surface waviness unlike the pad pattern 122, the bond finger 120 may provide a bonding region of a flat upper surface. Accordingly, the other end portion 234 of the wire may be sufficiently bonded to the surface of the plating pattern 124, so that the EFO defect that occurs when a tail does not grow when the wire is cut due to the surface waviness may be prevented. Accordingly, the process efficiency and yield in the wire bonding process may be improved.

In example embodiments, the molding member 300 may be provided on the upper surface 102 of the package substrate 100 to cover the semiconductor chip 200 and the bonding wires 230. The molding member 300 may include a thermosetting resin, for example, an epoxy mold compound (EMC).

In example embodiments, the lower substrate pads 130 for providing an electric signal may be formed on the lower surface 104 of the package substrate 100. The lower substrate pads 130 may be exposed by the lower protective layer 118. The lower protective layer 118 may include a silicon oxide layer, a silicon nitride layer, or a silicon oxynitride layer. The external connection member 160 may be arranged on the lower substrate pads 130 of the package substrate 100 for electrical connection with an external device. For example, the external connection member 160 may be a solder ball. The semiconductor package 10 may be mounted on a module substrate (not illustrated) via the solder balls to constitute a memory module.

As mentioned above, the semiconductor package 10 may include the package substrate 100 having the plurality of bond fingers 120, the semiconductor chip 200 disposed on the package substrate 100 and having the plurality of chip pads 210, and the bonding wires 230 that electrically connect the plurality of chip pads 210 and the plurality of bond fingers 120. Each of the bond fingers 120 may include the pad pattern 122 extending within the recess R and having the geometric characteristic of surface waviness, and the plating pattern 124 covering the surface of the pad pattern 122 and having the geometric characteristic of the predetermined surface roughness.

The plating pattern 124 may be formed by forming a preliminary plating pattern on the pad pattern 122 by a plating process and then flattening a surface of the preliminary plating pattern. Since the preliminary plating pattern is formed along the surface profile of the pad pattern 122, the preliminary plating pattern may have a surface waviness that is the same as or similar to the surface waviness of the pad pattern 122. By pressing the surface of the preliminary plating pattern using a flattening apparatus, the geometric characteristic of the surface waviness may be removed from the surface profile of the preliminary plating pattern.

Accordingly, since the plating pattern 124 does not have the geometric characteristic of the surface waviness, the bond finger 120 may provide a flat upper surface. In addition, since the plating pattern 124 has the geometric characteristics of the predetermined surface roughness, the process efficiency and yield in the wire bonding process may be improved.

Hereinafter, a method of manufacturing the semiconductor package of FIG. 1 will be described.

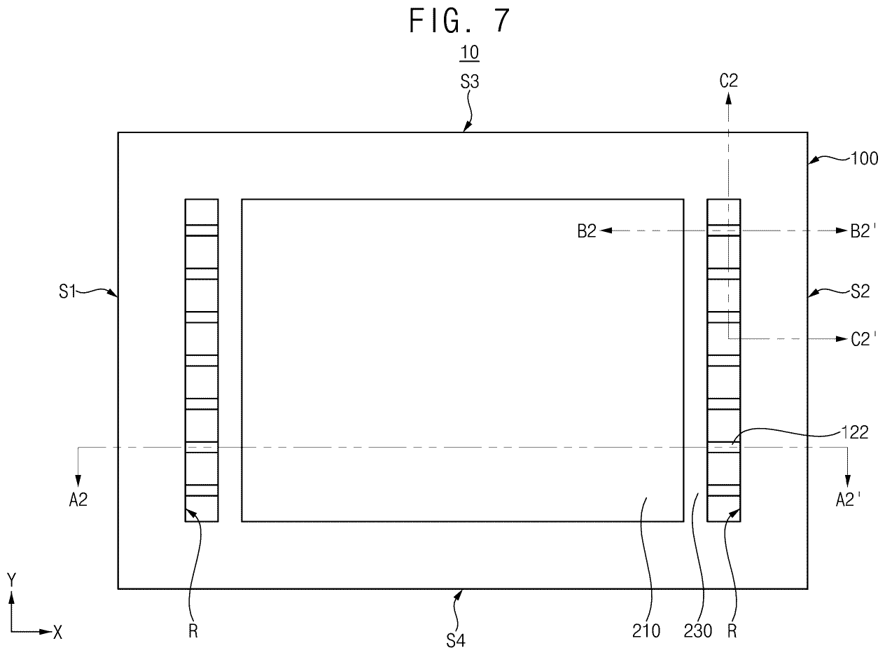

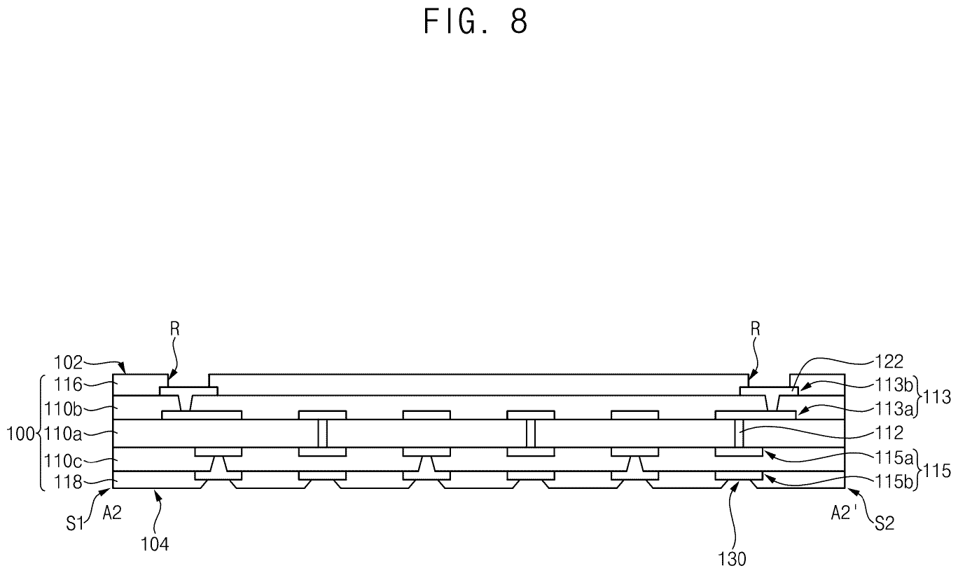

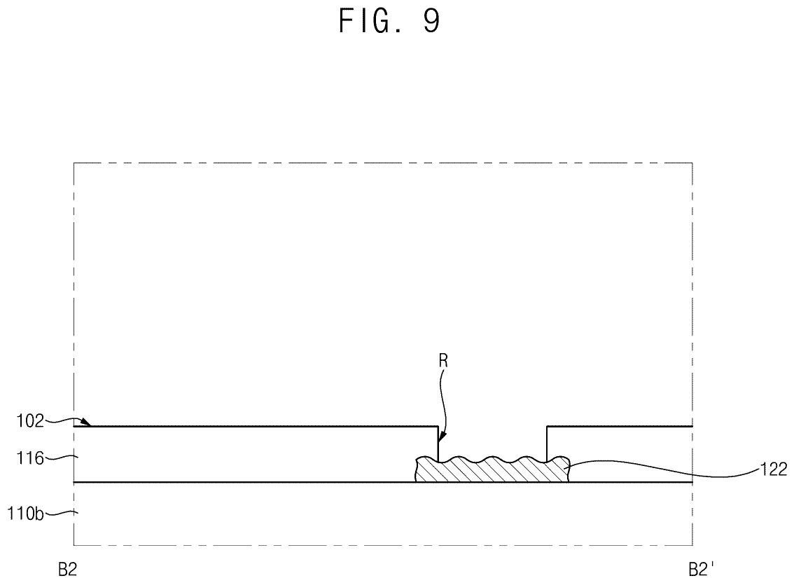

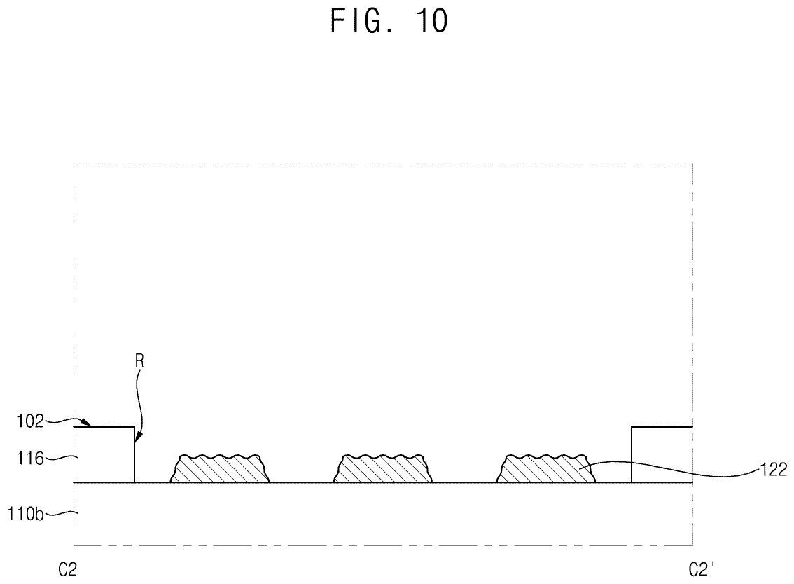

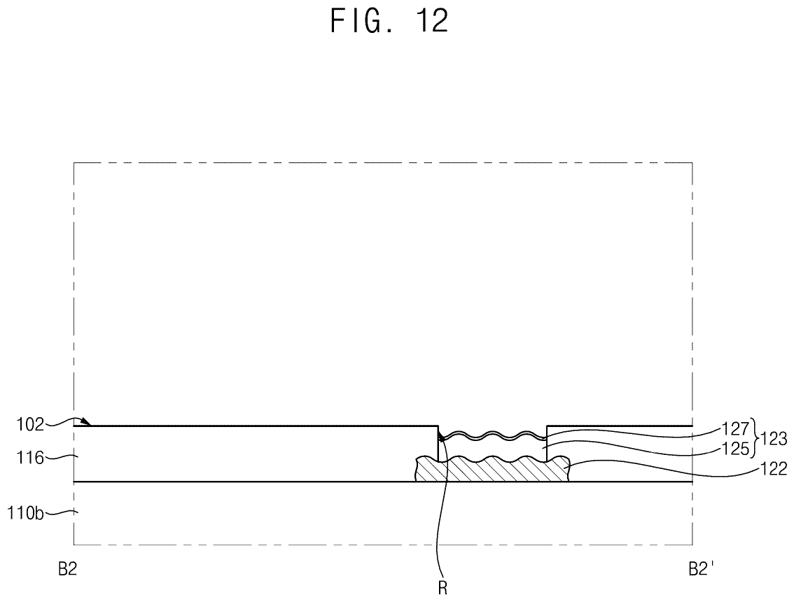

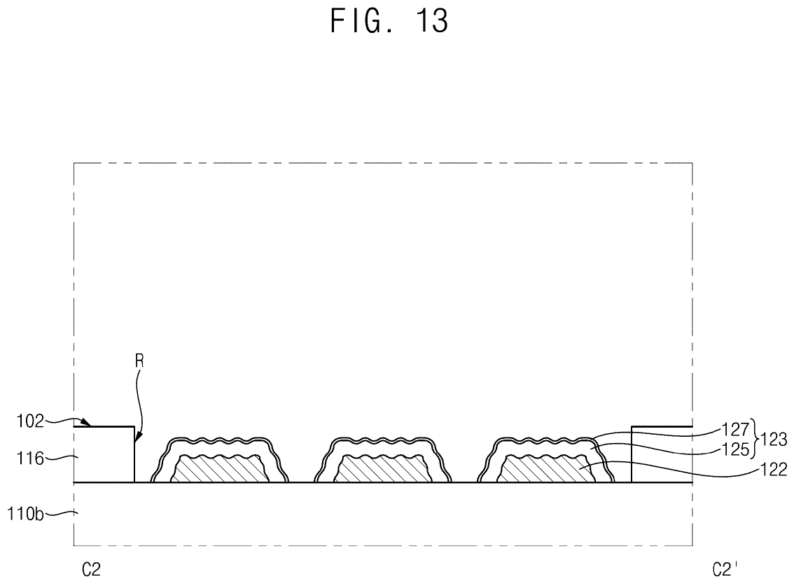

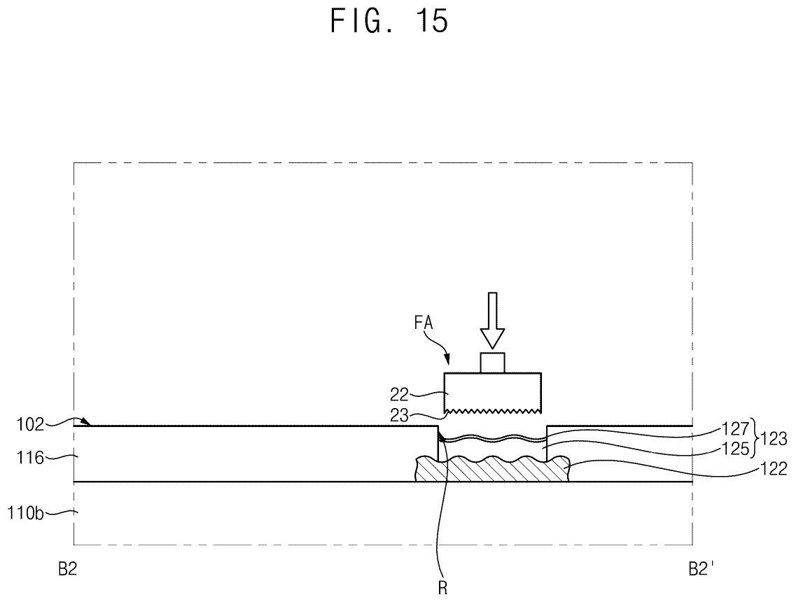

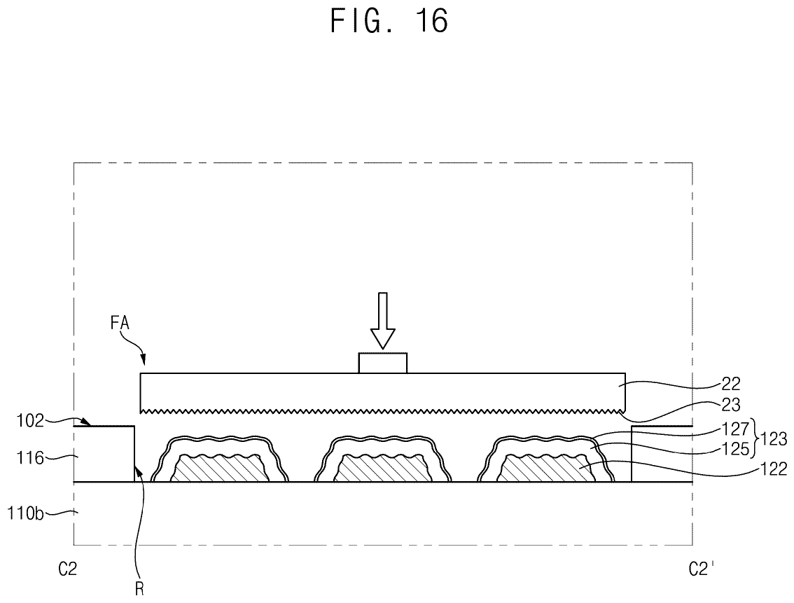

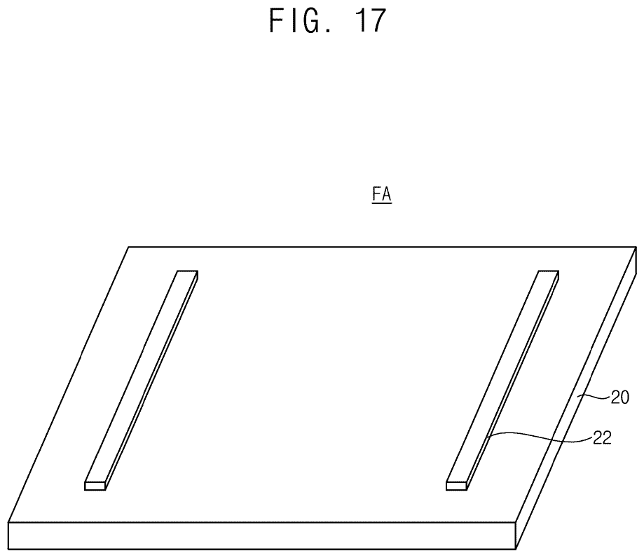

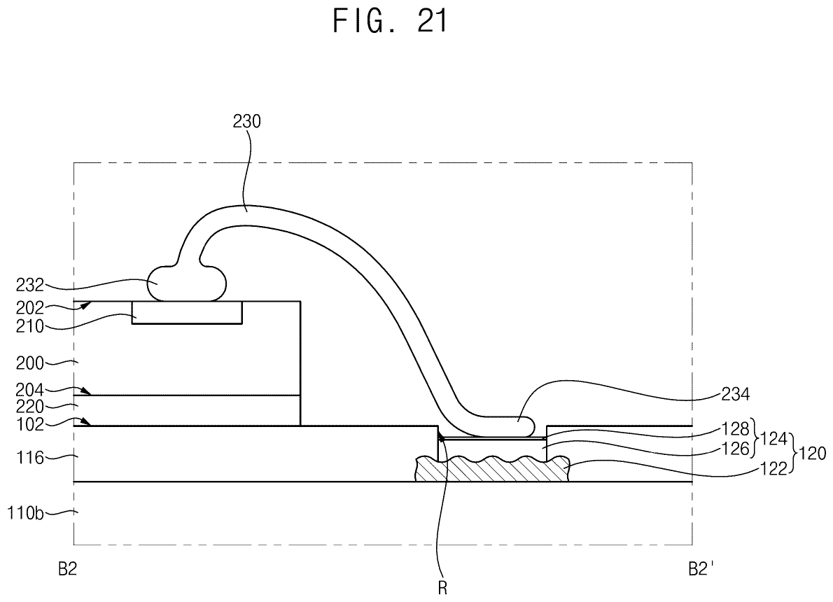

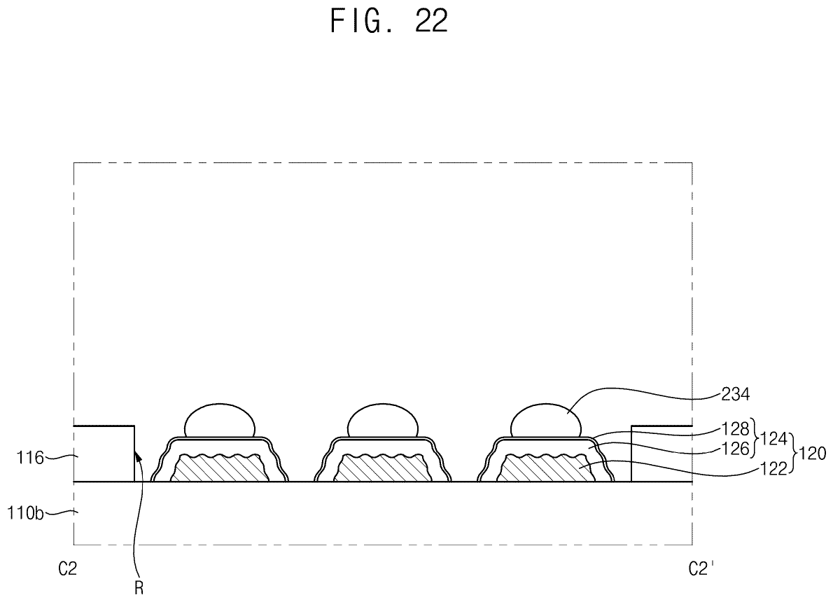

FIGS. 7 to 22 are views illustrating a method for manufacturing a semiconductor package in accordance with example embodiments. FIG. 7 is a plan view illustrating a method of manufacturing a semiconductor package in accordance with example embodiments. FIGS. 8, 11, 14, and 20 are cross-sectional views taken along the line A2-A2′ in FIG. 7. FIGS. 9, 12, 15, 18, and 21 are cross-sectional views taken along the line B2-B2′ in FIG. 7. FIGS. 10, 13, 16, 19, and 22 are cross-sectional views taken along the line C2-C2′ in FIG. 7. FIG. 17 is a perspective view illustrating a pressurizing plate of a flattening apparatus in accordance with example embodiments.

Referring to FIGS. 7 to 10, a package substrate 100 having a recess R that exposes a plurality of pad patterns 122 may be provided.

In example embodiments, the package substrate 100 may be a multilayer circuit board having an upper surface 102 and a lower surface 104 opposite to the upper surface 102. For example, the package substrate 100 may be a printed circuit board PCB including wirings provided in each of the plurality of layers and vias for connecting them.

The package substrate 110 may include a first side portion S1 and a second side portion S2 extending in a direction parallel to a second direction (Y direction) and facing each other, and a third side portion S3 and a fourth side portion S4 extending in a direction parallel to a first direction (X direction) perpendicular to the second direction and facing each other.

As illustrated in FIG. 8, the package substrate 100 may include a plurality of insulating layers 110a, 110b, 110c and wirings 113, 115 provided in the insulating layers respectively.

In particular, the package substrate 100 may include a core layer 110a, an upper insulating layer 110b on an upper surface of the core layer 110a, and a lower insulating layer 110c on a lower surface of the core layer 110a. The package substrate 100 may include a plurality of through vias 112 penetrating the core layer 110a, first upper circuit wirings 113a on the upper surface of the core layer 110a, second upper circuit wirings 113b provided in or on the upper insulating layer 110b, first lower circuit wirings 115a on the lower surface of the core layer 110a, and second lower circuit wirings 115b provided in or on the lower insulating layer 110c.

For example, the insulating layers 110a, 110b, 110c may include an insulating material such as a thermosetting resin such as epoxy resin or a thermoplastic resin such as polyimide. The insulating layer may include a resin impregnated in a core material such as organic fiber (glass fiber), for example, a prepreg, FR-4, BT (Bismaleimide Triazine), etc.

In example embodiments, the second upper circuit wirings 113b may include a plurality of pad patterns 122 that are exposed through a recess R and serve as portions of the bond fingers (finger bodies).

In particular, a seed layer and a first photoresist layer may be sequentially formed on an upper surface of the upper insulating layer 110b, and the first photoresist layer may be patterned to form a first photoresist pattern having first openings that expose the finger body regions. For example, the seed layer may include copper (Cu). The seed layer may have a thickness within a range of 0.1 μm to 2 μm.

Then, a plating process may be performed to fill the first openings of the first photoresist pattern with copper (Cu), to form the second upper circuit wirings 113b including the pad patterns 122. Then, portions of the seed layer exposed from the second upper circuit wirings may be removed.

The second upper circuit wiring 113b may extend on the upper insulating layer 110b and may include a trace including the pad pattern and a via pattern that is electrically connected to the first upper circuit wiring 113a through an opening formed in the upper insulating layer 110b.

Then, an upper protective layer 116 may be formed on the upper surface of the upper insulating layer 110b to cover the second upper circuit wirings 113b, and the recess R may be formed in the upper protective layer 116 to expose the plurality of pad patterns 122.

For example, a solder resist layer may be formed on the upper surface of the upper insulating layer 110b, and an exposure and development process may be performed to form the upper protective layer 116 having the recess R. The upper protective layer 116 may cover the entire upper surface of the upper insulating layer 110b except for the pad patterns 122. An upper surface of the upper protective layer 116 may be provided as the upper surface 102 of the package substrate 100.

For example, two recesses R may extend in the second direction (Y direction) along or adjacent the first side portion S1 and the second side portion S2 of the package substrate 100, respectively. The recess R may be elongated and may have, for example, a rectangular shape. The plurality of pad patterns 122 may be spaced apart from each other along the second direction (Y direction) within the recess R. Each of the pad patterns 122 may extend within the recess R in the first direction (X direction). The pad patterns 122 may be exposed from a bottom surface of the recess R. A thickness of the pad pattern 122 may be within a range of 5 μm to 30 μm. A width of the pad pattern 122 in the first direction (X direction) may be within a range of 30 μm to 40 μm.

In addition, a lower protective layer 118 may be formed on the lower surface of the lower insulating layer 110c to cover the second lower circuit wirings 115b. A lower surface of the lower protective layer 118 may be provided as the lower surface 104 of the package substrate 100. At least a portion of a pad of the second lower circuit wiring 115b may be provided as a lower substrate pad 130.

As illustrated in FIGS. 9 and 10, each of the pad patterns 122 formed by the plating process may have a geometric characteristic of surface waviness. Each of the pad patterns 122 may further have a geometric characteristic of surface roughness. A vertical distance (profile height) between a lowest point and a highest point of the surface profile of the pad pattern 122 may be within a range of 2 μm to 10 μm.

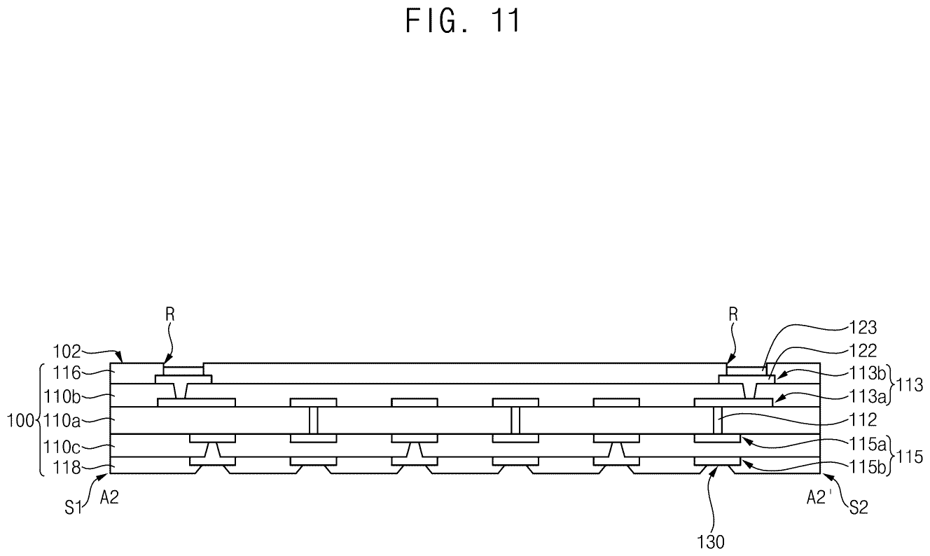

Referring to FIGS. 11 to 13, preliminary plating patterns 123 may be formed on the plurality of pad patterns 122 within the recess R, respectively.

In example embodiments, a first plating process may be performed to form a first preliminary plating pattern 125 on the pad pattern 122, and a second plating process may be performed to form a second preliminary plating pattern 127 on the first preliminary plating pattern 125. The preliminary plating pattern 123 may include the first preliminary plating pattern 125 and the second preliminary plating pattern 127 on the first preliminary plating pattern 125.

For example, the first preliminary plating pattern 125 may include nickel (Ni), and the second preliminary plating pattern 127 may include gold (Au). The first preliminary plating pattern 125 may have a thickness within a range of 4 μm to 8 μm, and the second preliminary plating pattern 127 may have a thickness within a range of 0.1 μm to 1.5 μm.

Since the first preliminary plating pattern 125 is formed along the surface profile of the pad pattern 122 and the second preliminary plating pattern 127 is formed along a surface profile of the first preliminary plating pattern 125, the preliminary plating pattern 123 may have a surface waviness that is the same as or similar to the surface waviness of the pad pattern 122.

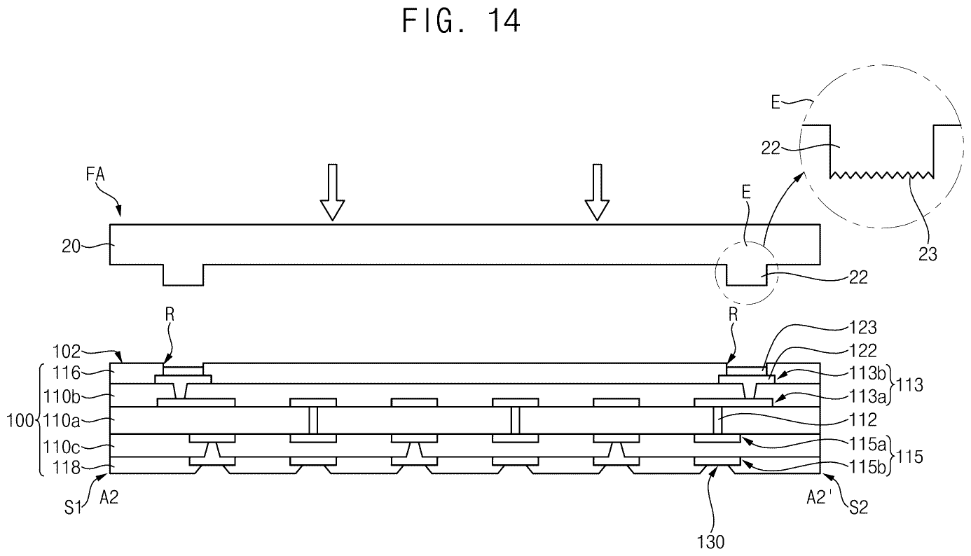

Referring to FIGS. 14 to 19, a surface of the preliminary plating pattern 123 may be flattened to form a plating pattern 124 having a geometric characteristic of a predetermined surface roughness.

As illustrated in FIGS. 14 to 17, in example embodiments, the surface of the preliminary plating pattern 123 may be pressurized using a flattening apparatus FA, and the geometric characteristic of the surface waviness in the surface profile of the preliminary plating pattern 123 may be removed or changed.

The flattening apparatus FA may include a base plate 20 and a protrusion portion 22 having a pressurizing surface 23. The base plate 20 may have a size corresponding to the upper protective layer 116, and the protrusion portion 22 may have a size corresponding to the recess R formed in the upper protective layer 116. As the base plate 20 is moved downwardly, the pressurizing surface 23 of the protrusion portion 22 may contact and press the surface of the preliminary plating pattern 123. The base plate 20 and the protrusion portion 22 may include a metal material such as stainless steel. The flattening apparatus FA may further include a heater for heating the base plate 20. When flattening the surface of the preliminary plating pattern 123, the temperature of the protrusion portion 22 that contacts and presses the surface of the preliminary plating pattern 123 may be controlled by the heater. It will be understood that the base plate 20 and the protrusion portion 22 of the flattening apparatus FA may have various structures depending on the arrangement of the bond fingers 120 of the package substrate 100 and the number and shape of the recesses.

Here, the pressurizing surface 23 may have a geometric characteristic of a predetermined surface roughness. Accordingly, surface roughness of the pressurizing surface 23 may be transferred to the surface of the preliminary plating pattern 123, so that the plating pattern 124 may have a geometric characteristic of the predetermined surface roughness. For example, an average roughness of the surface profile of the plating pattern 124 may be within a range of 0.1 μm to 1 μm.

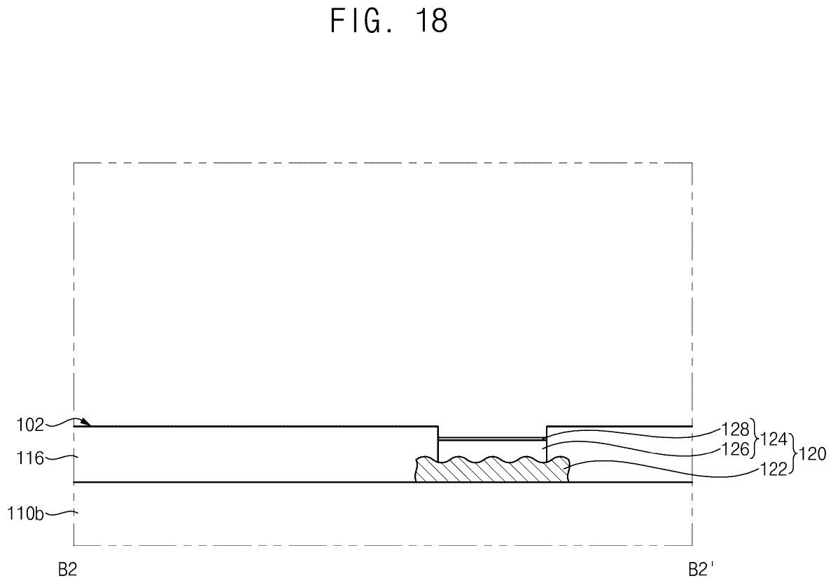

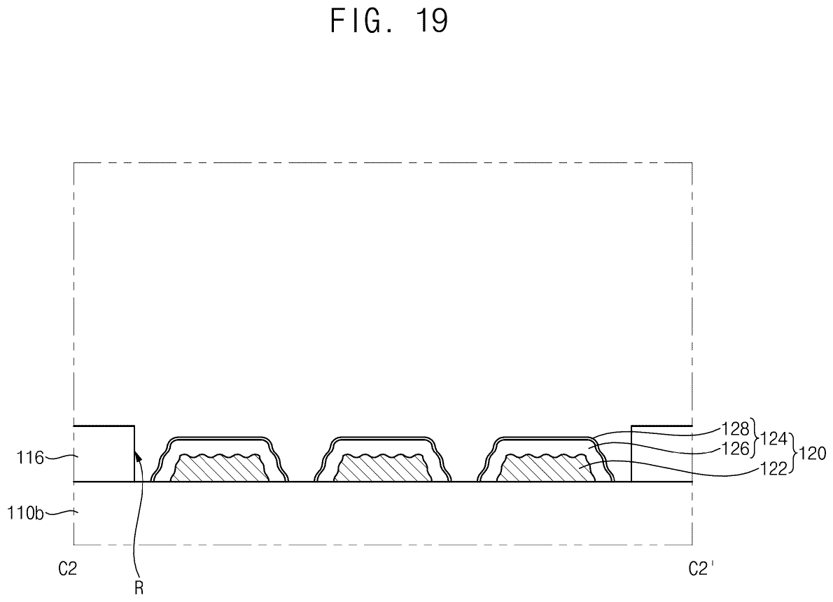

As illustrated in FIGS. 18 and 19, the pad pattern 122 in the recess R and the plating pattern 124 on the pad pattern 122 may be provided as a bond finger 120 that provides a plane on which a bonding wire is bonded. Since the plating pattern 124 does not have a geometric characteristic of a surface waviness, the bond finger 120 may provide a flat upper surface. In addition, since the plating pattern 124 has the geometric characteristic of the predetermined surface roughness, the process efficiency and yield in a following wire bonding process may be improved.

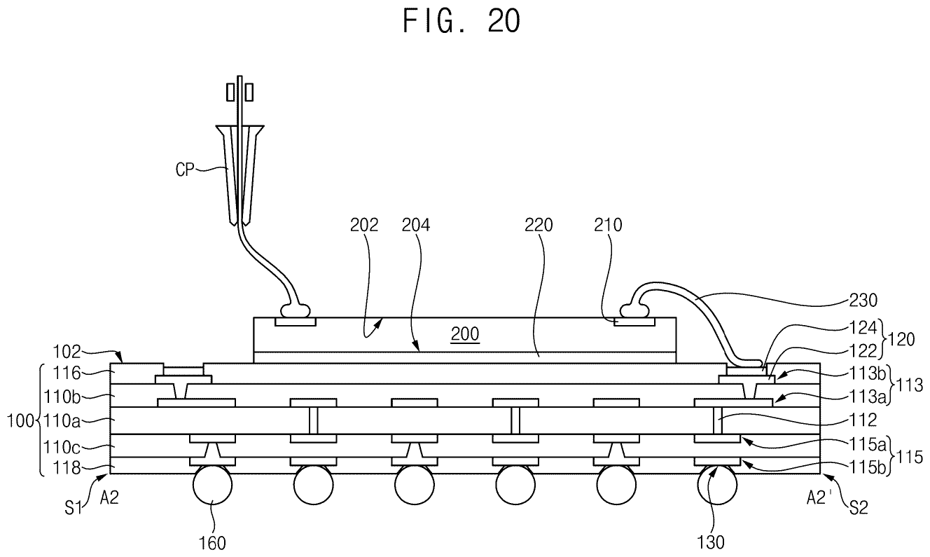

Referring to FIGS. 20 to 22, at least one semiconductor chip 200 may be mounted on the package substrate 100 by a wire bonding method.

In example embodiments, the at least one semiconductor chip 200 may be placed on the package substrate 100. The semiconductor chip 200 may be attached to the upper protective layer 116 of the package substrate 100 by an adhesive film 220. The semiconductor chip 200 may be arranged such that a surface 204 (e.g., a back surface or lower surface) opposite to a front surface 202 (e.g., upper surface) on which chip pads 210 are formed, that is, an active surface, faces the package substrate 100. The semiconductor chip 200 may have a rectangular shape with four sides when viewed in a plan view. The chip pads 210 may be arranged on the front surface 202 of the first semiconductor chip 200 to be spaced apart from each other along first and second sides facing each other. For example, a thickness of the semiconductor chip 200 may be within a range of 40 μm to 120 μm. A thickness of the adhesive film 220 may be within a range of 5 μm to 30 μm.

Then, a wire bonding process may be performed to connect the chip pads 210 of the semiconductor chip 200 to the bond fingers 120 of a package substrate 100. The chip pads 210 of the semiconductor chip 200 may be connected to the bond fingers 120 by bonding wires 230 as conductive connection members.

In particular, a free air ball FAB may be formed at one end portion 232 of a wire drawn from a capillary CP and bonded to the chip pad 210 of the semiconductor chip 200, and then the capillary CP may move in a vertical direction to draw out the wire. Then, the capillary CP may move the wire onto the bond finger 120 within the recess R to contact the surface of the plating pattern 124, and then cut a portion of the wire. When cutting the portion of the wire, a free air ball FAB may be formed in the cutting portion of the wire through EFO (Electronic Flame Off) and may be moved to another chip pad to continue the bonding wire process.

Since the plating pattern 124 does not have the geometric characteristics of surface waviness unlike the pad pattern 122, the bond finger 120 may provide a bonding region of a flat upper surface. Accordingly, the other end portion 234 of the wire may be sufficiently bonded to the surface of the pad pattern 122, so as to prevent the EFO defect that occurs when a tail does not grow due to the surface waviness when the wire is cut. Accordingly, the wire bonding process can be improved.

Then, a molding member (300, see FIG. 2) may be formed on the upper surface 102 of the package substrate 100 to cover the semiconductor chip 200 and the bonding wires 230. The molding member may include a thermosetting resin, for example, an epoxy mold compound (EMC).

Then, external connection members (160, see FIG. 2) may be formed on the lower substrate pads 130 on the lower surface 104 of the package substrate 100 to complete the semiconductor package 10 of FIG. 1.

For example, the external connection members may include solder balls. The external connection members may be formed on the lower substrate pads 130 of the package substrate 100 by a solder ball attach process, respectively.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present inventive concept. Accordingly, all such modifications are intended to be included within the scope of example embodiments as defined in the claims.

What is claimed is:

1. A package substrate, comprising:
at least one insulating layer;
upper circuit wirings having a plurality of pad patterns that extend on the at least one insulating layer; and
a plurality of plating patterns respectively on the plurality of pad patterns,
wherein each of the plurality of pad patterns has a geometric characteristic of surface waviness, and
wherein each of the plurality of plating patterns covers a surface of each of the pad patterns and has a geometric characteristic of predetermined surface roughness.

2. The package substrate of claim 1, wherein a vertical distance between a lowest point and a highest point of a surface profile of each of the pad patterns is within a range of 2 μm to 10 82 m.

3. The package substrate of claim 1, wherein an average roughness of a surface profile of each of the plating patterns is within a range of 0.1 μm to 1 μm.

4. The package substrate of claim 1, wherein each of the pad patterns further has a geometric characteristic of surface roughness.

5. The package substrate of claim 1, wherein each of the pad patterns includes copper (Cu).

6. The package substrate of claim 1, wherein each of the plurality of plating patterns includes:
a first plating pattern on the pad pattern; and
a second plating pattern on the first plating pattern.

7. The package substrate of claim 6, wherein the first plating pattern includes nickel (Ni) and the second plating pattern includes gold (Au).

8. The package substrate of claim 6, wherein the first plating pattern has a thickness within a range of 4 μm to 8 μm, and the second plating pattern has a thickness within a range of 0.1 μm to 1.5 μm.

9. The package substrate of claim 1, further comprising:
an upper protective layer covering the at least one insulating layer and having a recess that exposes the plurality of pad patterns.

10. The package substrate of claim 9, wherein the recess has a rectangular shape extending in a first direction in which the plurality of pad patterns are spaced apart from each other.

11. A package substrate, comprising:
a plurality of insulating layers;
upper circuit wirings having a plurality of pad patterns that extend on an uppermost insulating layer among the plurality of insulating layers;
an upper protective layer covering the uppermost insulating layer and having a recess that expose the plurality of pad patterns; and
a plurality of plating patterns respectively on the plurality of pad patterns that are exposed within the recess,
wherein each of the plurality of pad patterns exposed within the recess has a geometric characteristic of surface waviness, and
wherein each of the plurality of plating patterns has a geometric characteristic of predetermined surface roughness.

12. The package substrate of claim 11, wherein a vertical distance between a lowest point and a highest point of a surface profile of each of the pad patterns is within a range of 2 μm to 10 μm.

13. The package substrate of claim 11, wherein an average roughness of a surface profile of each of the plating patterns is within a range of 0.1 μm to 1 μm.

14. The package substrate of claim 11, wherein each of the pad patterns further has a geometric characteristic of surface roughness.

15. The package substrate of claim 11, wherein each of the pad patterns includes copper (Cu).

16. The package substrate of claim 11, wherein each of the plurality of plating patterns includes:
a first plating pattern on the pad pattern; and
a second plating pattern on the first plating pattern.

17. The package substrate of claim 16, wherein the first plating pattern includes nickel (Ni) and the second plating pattern includes gold (Au).

18. The package substrate of claim 16, wherein the first plating pattern has a thickness within a range of 4 μm to 8 μm, and the second plating pattern has a thickness within a range of 0.1 μm to 1.5 μm.

19. The package substrate of claim 11, wherein the recess has a rectangular shape extending in a first direction in which the plurality of pad patterns are spaced apart from each other.

20. A semiconductor package, comprising:
a package substrate including a plurality of bond fingers;
at least one semiconductor chip on the package substrate and including a plurality of chip pads; and
bonding wires electrically connecting the plurality of chip pads and the plurality of bond fingers,
wherein each of the plurality of bond fingers includes:
a pad pattern on an upper surface of the package substrate and having a geometric characteristic of surface waviness; and
a plating pattern covering a surface of the pad pattern and having a geometric characteristic of predetermined surface roughness,
wherein one end portion of the bonding wire is bonded to an upper surface of the plating pattern of a corresponding bond finger,
wherein a vertical distance between a lowest point and a highest point of a surface profile of the pad pattern is within a range of 2 μm to 10 μm, and
wherein an average roughness of a surface profile of the plating pattern is within a range of 0.1 μm to 1 μm.
